(19) United States
(12) Patent Application Publication
(10) Pub. No.: US 2026/0096494 A1
(43) Pub. Date: Apr. 2, 2026

(54) HYBRID SILICON CAP LSC TO INCREASE BGA DENSITY

(71) Applicant: QUALCOMM Incorporated, San Diego, CA (US)

(72) Inventors: Aniket PATIL, San Diego, CA (US); Manuel ALDRETE, Encinitas, CA (US); Piyush GUPTA, San Diego, CA (US)

(21) Appl. No.: 18/900,172

(22) Filed: Sep. 27, 2024

(51) Int. Cl. H01L 23/498; H01L 21/56; H01L 21/60; H01L 23/31

(52) U.S. Cl. CPC H10W 90/701; H10W 70/635; H10W 74/016; H10W 74/131; H10W 72/072; H10W 72/247

(57) ABSTRACT

Disclosed are semiconductor packages. A semiconductor package may include a substrate with a ball grid array (BGA) on a lower surface thereof. The semiconductor package may also comprise a die on an upper surface of the substrate, and a land-side component (LSC) on the lower surface of the substrate. One or more edge terminals may be formed on one or more edges of the LSC. At least one edge terminal may comprise an edge insulator and an edge conductor. The edge terminals allows a substantial reduction in the keep-out-zone. As a result, more BGA balls may be provided.

### BACKGROUND OF THE DISCLOSURE

### 1. Field of the Disclosure

This disclosure relates generally to die packages or modules, and more specifically, but not exclusively, to semiconductor packages/modules that include hybrid silicon cap land side capacitors (LSC) to increase ball grid array (BGA) density and fabrication techniques thereof.

### 2. Description of the Related Art

In semiconductor packages that include land-side components (LSC), underfill (UF) is used for silicon based capacitors for reliability. Unfortunately, there is a substantial ball grid array (BGA) loss due to LSC placement keep out zone (KOZ). This can lead to ball count loss for a given silicon capacitor size. Accordingly, there is a need for systems, apparatus, and methods that overcome the deficiencies of conventional semiconductor packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor package is disclosed. The semiconductor package may comprise a substrate with a ball grid array (BGA) on a lower surface thereof. The BGA may comprise one or more balls. The semiconductor package may also comprise a die on an upper surface of the substrate. The semiconductor package may further comprise a land-side component (LSC) on the lower surface of the substrate. The semiconductor package may yet comprise one or more edge terminals on one or more edges of the LSC. At least one edge terminal may comprise an edge insulator in contact with a side edge portion, an upper edge portion, and a lower edge portion. The side edge portion may be a portion of a side surface of the LSC. The upper edge portion may be a portion of an upper surface of the LSC near the side edge portion. The lower edge portion may be a portion of a lower surface of the LSC near the side edge portion.

A method of fabricating a semiconductor package is disclosed. The method may comprise a forming substrate with a ball grid array (BGA) on a lower surface thereof. The BGA may comprise one or more balls. The method may also comprise providing a die on an upper surface of the substrate. The method may further comprise providing a land-side component (LSC) on the lower surface of the substrate. The method may yet comprise forming one or more edge terminals on one or more edges of the LSC. At least one edge terminal may comprise an edge insulator in contact with a side edge portion, an upper edge portion, and a lower edge portion. The side edge portion may be a portion of a side surface of the LSC. The upper edge portion may be a portion of an upper surface of the LSC near the side edge portion. The lower edge portion may be a portion of a lower surface of the LSC near the side edge portion.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIGS. 1A and 1B respectively illustrate cross sectional and bottom views of a conventional semiconductor package.

FIGS. 2A and 2B respectively illustrate cross sectional and bottom views of a semiconductor package in accordance with one or more aspects of the disclosure.

FIG. 3 illustrates another semiconductor package in accordance with one or more aspects of the disclosure.

FIGS. 4A and 4B illustrate examples of edge terminals of a semiconductor package in accordance with one or more aspects of the disclosure.

FIG. 5A-5D illustrate examples of stages of fabricating a land-side component of a semiconductor package in accordance with one or more aspects of the disclosure.

FIG. 6A-6B illustrate examples of stages of fabricating a semiconductor package in accordance with one or more aspects of the disclosure.

FIG. 7-10 illustrate flow charts of example methods of manufacturing a semiconductor package in accordance with at one or more aspects of the disclosure.

FIG. 11 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor packages and methods for fabricating the same. In an aspect, The semiconductor package may comprise a substrate with a ball grid array (BGA) on a lower surface thereof. The BGA may comprise one or more balls. The semiconductor package may also comprise a die on an upper surface of the substrate. The semiconductor package may further comprise a land-side component (LSC) on the lower surface of the substrate. The semiconductor package may yet comprise one or more edge terminals on one or more edges of the LSC. At least one edge terminal may comprise an edge insulator in contact with a side edge portion, an upper edge portion, and a lower edge portion. The side edge portion may be a portion of a side surface of the LSC. The upper edge portion may be a portion of an upper surface of the LSC near the side edge portion. The lower edge portion may be a portion of a lower surface of the LSC near the side edge portion. In this way, interconnects between the semiconductor package and PCB may be improved. Also, the keep-out-zone (KOZ) may be improved. Further, mechanical stability and joint reliability for the LSC may be improved.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to”perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

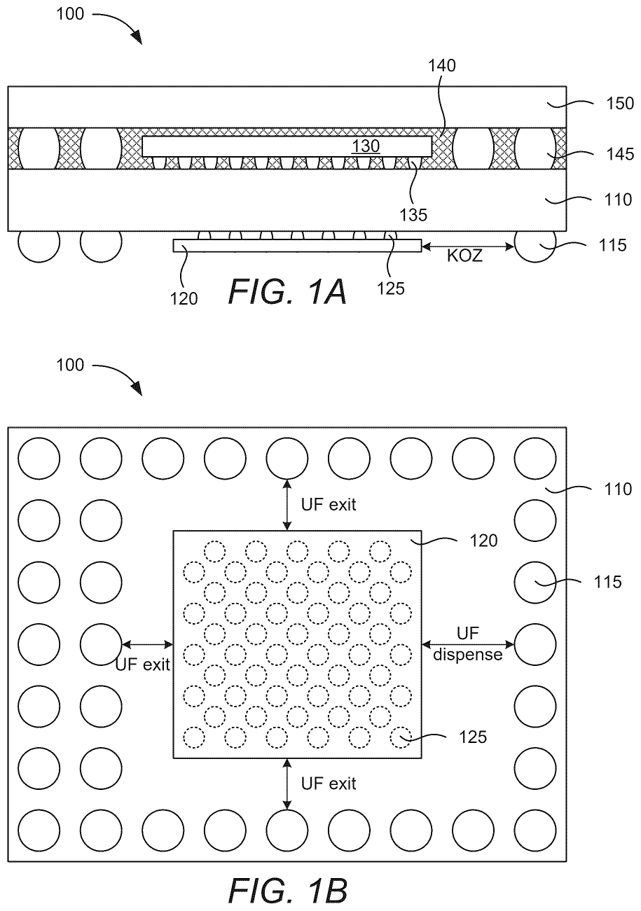

As indicated above, in semiconductor packages that include LSCs, underfill is used for silicon based capacitors for reliability. Unfortunately, there is a substantial BGA loss of due to LSC placement keep out zone (KOZ). This can lead to ball count loss for a given silicon capacitor size. FIGS. 1A and 1B respectively illustrate cross sectional and bottom views of a conventional semiconductor package 100. As seen, the conventional semiconductor package 100 includes a substrate 110 with a ball grid array (BGA) on a lower surface thereof. The BGA includes a plurality of balls 115. The conventional semiconductor package 100 also includes a system-on-chip (SoC) die 130 on an upper surface of the substrate 110, and a land-side component (LSC) on the lower surface of the substrate 110. Die pins 135 are formed on a lower surface of the die 130 and are in contact with the substrate 110. LSC pins 125 are formed on an upper surface of the LSC 120 and are in contact with the substrate 110. The conventional semiconductor package 100 further includes a mold 140 on the substrate 110, a passivation layer 150 on the mold 140. The mold 140 encapsulates side and upper surfaces of the die 130. A plurality of through-mold-vias (TMV) 145 are formed within the mold 140.

As noted above, FIG. 1B illustrates a bottom view of the conventional semiconductor package 100. In this view, bottom surfaces of the substrate 110 and of the LSC 120 are shown. Regarding the LSC 120, the LSC pins 125 are shown as dashed pins to indicate that they are on the upper surface of the LSC 120.

At least one challenge with respect to the conventional semiconductor package 100 is the BGA loss due to LSC placement KOZ. Typically, underfill (UF) is used for silicon-based capacitors for reliability. This is illustrated in FIG. 1B. The design rules dictate the UF exit and UF dispense KOZ distances. For the conventional semiconductor package 100, the UF exit distance is greater than 280 μm and the UF dispense distance is greater than 500 μm, which are quite substantial. The lengthy KOZ distances leads to ball count loss for chosen silicon capacitor size. This leads to power distribution network (PDN) efficient, and also limits performance of the semiconductor package 100. Another challenge is that mechanical stability and reliability can be decreased.

To address such issues, these and other issues of the conventional semiconductor package, it is proposed to increase BGA density through using edge terminals on the LSC. The proposed solution may include at least the following technical advantages: 1) improve interconnects between the semiconductor package and printed circuit board (PCB) near the LSC; 2) improve KOZ for deep trench capacitor (DTC) placement on the LSC; and 3) improve mechanical stability and joint reliability for the LSC.

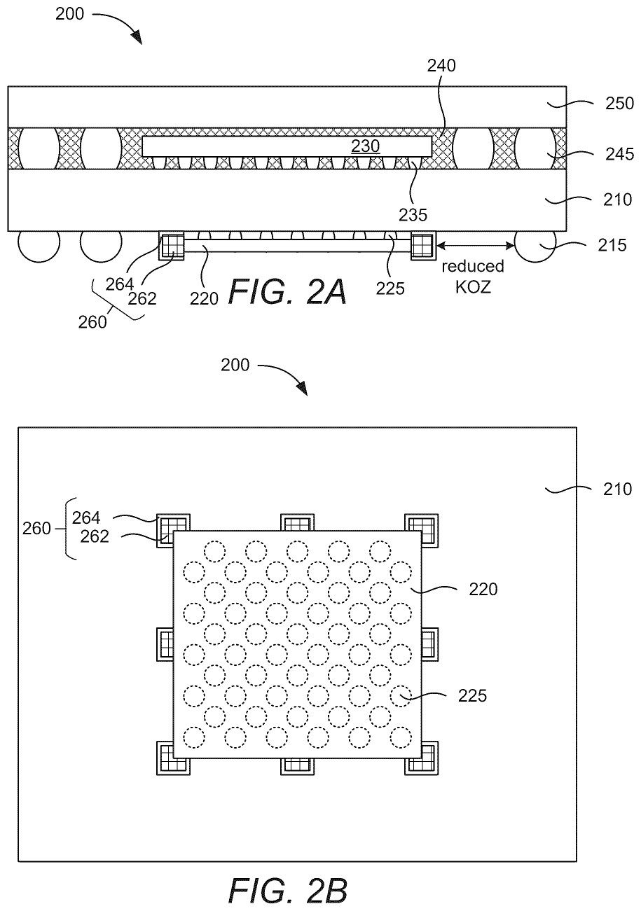

FIGS. 2A and 2B respectively illustrate cross sectional and bottom views of a semiconductor package 200 in accordance with one or more aspects of the disclosure. The semiconductor package 200 may include a substrate 210, a die 230 and a land-side component (LSC) 220. The substrate 210 may comprise a ball grid array BGA on a lower surface thereof. The BGA may comprise one or more balls 215, e.g., solder balls. The die 230 may be provided on an upper surface of the substrate 210, and the LSC 220 may be provided on the lower surface of the substrate 210. In an aspect, the LSC 220 may be a passive device, such as a capacitor. In another aspect, the die 230 may be a processor or a system-on-chip (SoS) die.

The die 230 may comprise one or more die pins 235 and the LSC 220 may comprise one or more LSC pins 225. The die pins 235 may be on, e.g., in contact with, the upper surface of the substrate 210. The LSC pins 225 may be on, e.g., in contact with, the lower surface of the substrate 210. There may be one or more circuits (e.g., redistribution layer (RDL)) within the substrate 210 (not shown). The die 230 and the LSC 220 may be electrically coupled to each other through the one or more die pins 235, the one or more LSC pins 225, and the one or more conductive circuits within the substrate 210. Again, in FIG. 2B, the LSC pins 225 are dashed to indicate may be formed on the upper surface of the LSC 220.

The semiconductor package 200 may also include a mold 240 on the substrate 210 and a passivation layer 250 on the mold 240. The mold 240 may encapsulate side and upper surfaces of the die 230. One or more through-mold vias (TMV) 245 may be formed within the mold 240. The one or more TMVs 245 may electrically couple one or more circuits within the passivation layer 250 (not shown) to the one or more circuits within the substrate 210.

The semiconductor package 200 may further include one or more edge terminals 260 on one or more edges of the LSC 220. In FIG. 2B, eight (8) such edge terminals 260 are shown. However, this is merely an example. That is, there may be any number of edge terminals 260. As seen in FIGS. 2A and 2B, the edge terminals 260 may include edge insulators 262 in contact with a side edge portion, an upper edge portion, and a lower edge portion of the LSC 220. The side edge portion may be defined as a portion of a side surface of the LSC 220. The upper edge portion may be defined as a portion of an upper surface of the LSC 220 near (or immediately adjacent to) the side edge portion. The lower edge portion may be defined as a portion of a lower surface of the LSC 220 near (or immediately adjacent to) the side edge portion. In other words, the edge terminals 260 may partially surround the upper, lower, and side portions of the LSC 220. One or more edge conductors 264 may be formed on side, upper and/or lower surfaces of the corresponding one or more edge insulators 262.

The edge terminals 260 may enable the KOZ design rules to be tightened. For clarity, KOZ in an aspect may be defined as a minimum distance between the edge conductor 262 and a nearest ball 215 of the BGA. In an aspect, the KOZ may be reduced to 150 μm or less. This can significantly increase BGA density. For example, the ball count for the conventional semiconductor package 100 may be limited to 28 or fewer. However, the ball count for the semiconductor package 200 can be more than 28.

Since the edge conductor 262 are conductive (e.g., may be formed of nickel (Ni), tin (Sn), copper (Cu), etc.), it can be used to carry signals and/or as a part of a power distribution network (PDN). For example, the edge conductor 262 may carry or otherwise provide power (e.g., Vdd, Vss, etc.) or ground to the die 230.

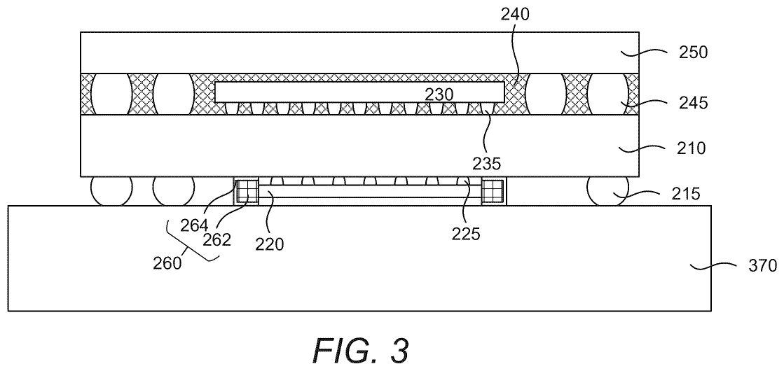

FIG. 3 illustrates another semiconductor package in accordance with one or more aspects of the disclosure. The semiconductor package of FIG. 3 may be similar to the semiconductor package 200 of FIGS. 2A and 2B. However, the semiconductor package of FIG. 3 may further include a printed circuit board (PCB) 370 below the substrate 210. In an aspect, the BGA and at least one edge terminal 260 may be electrically coupled to one or more circuits within the PCB 370 (not shown).

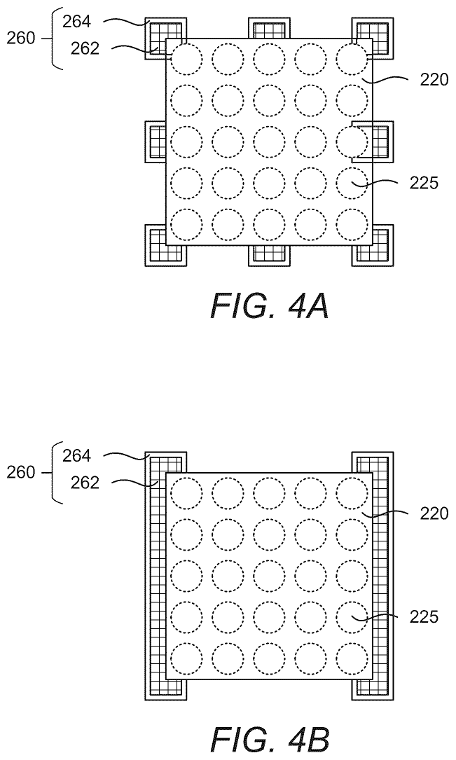

The layout and/or the number of the edge terminals 260 can be varied. This is illustrated in FIGS. 4A and 4B illustrate examples of edge terminals 260 of a semiconductor package 200 in accordance with one or more aspects of the disclosure. FIG. 4A illustrates an example where multiple edge terminals 260 are provided, each covering a part of a side or corners of the LSC 220. FIG. 4B illustrates an example where two edge terminals 260 are provided, each covering an entire side of the LSC 220. Further, as seen in FIG. 4A, the edge conductor 264 may be formed to electrically couple with the one or more LSC pins 225.

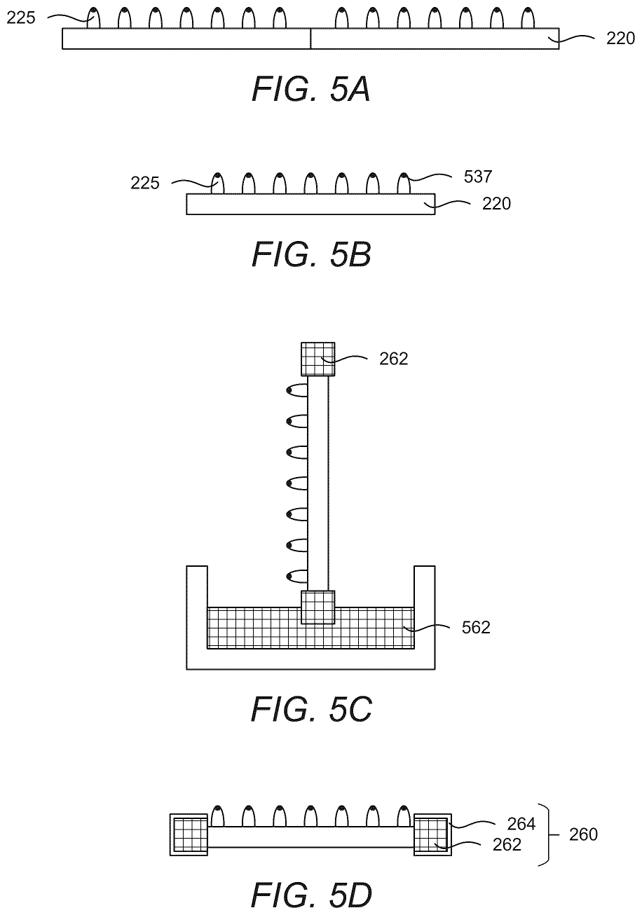

FIG. 5A-5D illustrate examples of stages of fabricating a land-side component (LSC)—such as the LSC 220—in accordance with one or more aspects of the disclosure. FIG. 5A illustrates a stage in which bumps 537—e.g., solder bumps—may be formed on the LSC pins 225 of the LSC 220. In an aspect, the LSC 220 may be one of a plurality of LSCs of a wafer. In this particular instance, two LSCs 220 are shown.

FIG. 5B illustrates a stage in which the LSC 220 may be singulated from the wafer.

FIG. 5C illustrates a stage in which one or more edges of the LSC 220 may be dipped in termination ink 562 to form one or more edge insulators 262.

FIG. 5D illustrates a stage in which conductive material (e.g., Ni, Sn, Cu, etc.) may be plated on the one or more edge insulators 262 to form corresponding one or more edge conductors 264.

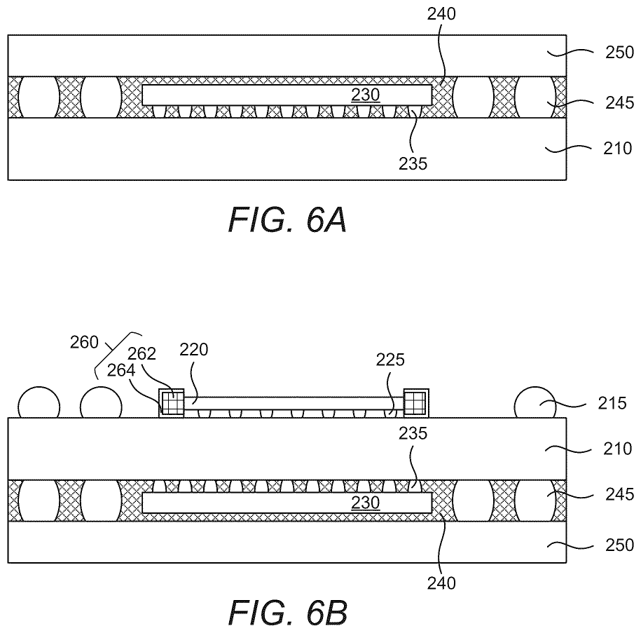

FIG. 6A-6B illustrate examples of stages of fabricating a semiconductor package—such as the semiconductor package 200—in accordance with one or more aspects of the disclosure. FIG. 6A illustrates a stage in which a package assembly comprising the die 230 on the upper surface of the substrate 210 may be provided. For ease of reference, the package may be referred to as the first package assembly. Note that the first package assembly may also include the mold 240, the passivation layer 250, and the TMVs 245 within the mold 240.

FIG. 6B illustrates a stage in which the LSC 220 along with the one or more edge terminals 260 may be attached or otherwise placed on the lower surface of the substrate 210. For ease of reference, the LSC 220 and the one or more edge terminals 260 may be referred to as the second package assembly. Then it may be said that FIG. 6B illustrates in which the second package assembly may be placed on the lower surface of the substrate 210. Note that the first package assembly may be flipped to ease the placing of the second package assembly.

FIG. 6B also illustrates a stage in which the balls 215 (e.g., solder balls) may be formed on the lower surface (now facing upward) of the substrate 210. Thereafter, a solder reflow may be performed. In an aspect, if the first package assembly is one of a multiple first package assemblies attached to each other (not shown), then a singulation may be performed.

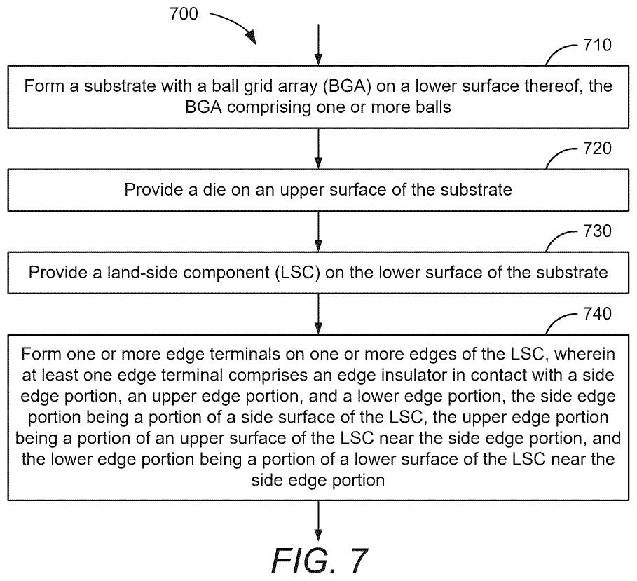

FIG. 7 illustrates a flow chart of an example method 700 of fabricating a semiconductor package, such as the semiconductor package 200, in accordance with at one or more aspects of the disclosure.

In block 710, a substrate 210 with a BGA on a lower surface thereof may be formed. The BGA may comprise one or more balls.

In block 720, a die 230 may be provided on an upper surface of the substrate 210.

In block 730, a land-side component (LSC) 220 may be provided on the lower surface of the substrate 210.

In block 740, one or more edge terminals 260 may be formed on one or more edges of the LSC 220. At least one edge terminal 260 may comprise an edge insulator 262 in contact with a side edge portion, an upper edge portion, and a lower edge portion of the LSC 220.

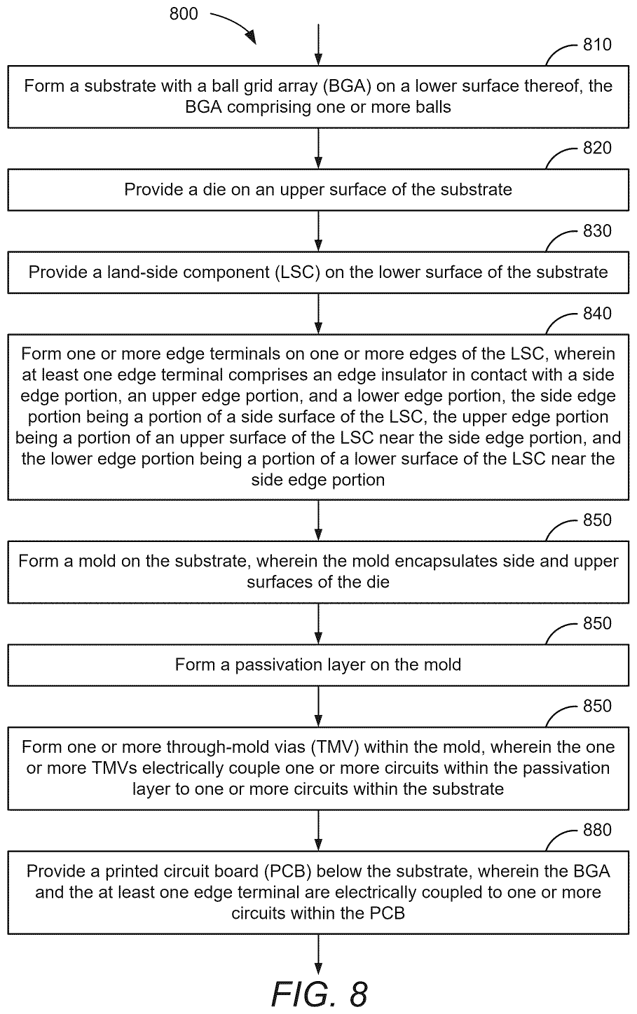

FIG. 8 illustrates a flow chart of an example method 800 of fabricating a semiconductor package, such as the semiconductor package 200 in accordance with at one or more aspects of the disclosure. FIG. 8 may be viewed as being more comprehensive than FIG. 7.

Block 810 may be similar to block 710. That is, in block 810, a substrate 210 with a BGA on a lower surface thereof may be formed. The BGA may comprise one or more balls.

Block 820 may be similar to block 720. That is, in block 820, a die 230 may be provided on an upper surface of the substrate 210.

Block 830 may be similar to block 730. That is, in block 830, a land-side component (LSC) 220 may be provided on the lower surface of the substrate 210.

Block 840 may be similar to block 740. That is, in block 840, one or more edge terminals 260 may be formed on one or more edges of the LSC 220. At least one edge terminal 260 may comprise an edge insulator 262 in contact with a side edge portion, an upper edge portion, and a lower edge portion of the LSC 220.

In block 850, a mold 240 may be formed on the substrate 210. The mold 240 may encapsulate side and upper surfaces of the die 230.

In block 860, a passivation layer 250 may be formed on the mold 240.

In block 870, one or more through-mold vias (TMV) 245 may be formed within the mold 240. The one or more TMVs 245 may electrically couple one or more circuits within the passivation layer 250 to one or more circuits within the substrate 210.

In block 880, a printed circuit board (PCB) 370 may be provided below the substrate 210. The BGA and the at least one edge terminal 260 may be electrically coupled to one or more circuits within the PCB 370.

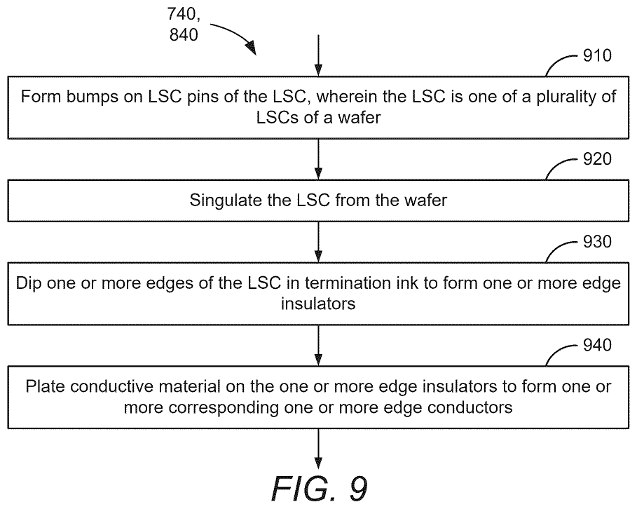

FIG. 9 illustrates a flow chart of an example process to perform block 740 of FIG. 7 (and hence block 840 of FIG. 8). In block 910, bumps 537 may be formed on LSC pins 225 of the LSC 220. In an aspect, the LSC 220 may be one of a plurality of LSCs of a wafer. Block 910 may correspond to the stage illustrated in FIG. 5A.

In block 920, the LSC 220 may be singulated from the wafer. Block 920 may correspond to the stage illustrated in FIG. 5B.

In block 930, one or more edges of the LSC 220 may be dipped in termination ink 562 to form one or more edge insulators 262. Block 930 may correspond to the stage illustrated in FIG. 5C.

In block 940, conductive material may be plated on the one or more edge insulators 262 to form corresponding one or more edge conductors 264. Block 940 may correspond to the stage illustrated in FIG. 5D.

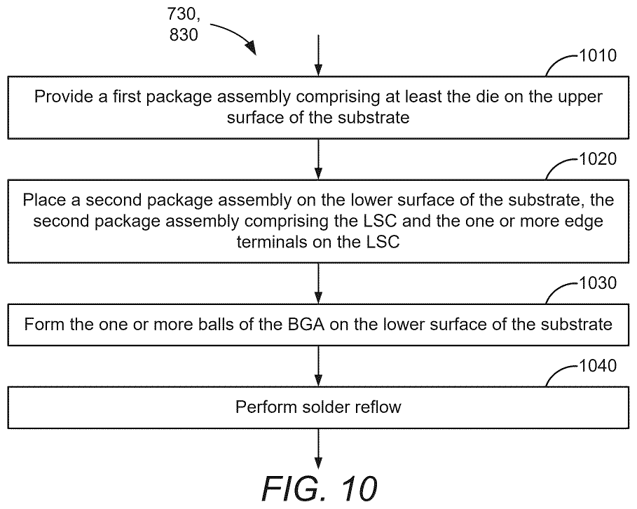

FIG. 10 illustrates a flow chart of an example process to perform block 730 of FIG. 7 (and hence block 830 of FIG. 8). In block 1010, a first package assembly may be provided. The first package assembly may comprise at least the die 230 on the upper surface of the substrate 210. Block 1010 may correspond to the stage illustrated in FIG. 6A.

In block 1030, a second package assembly may be placed on the lower surface of the substrate 210. The second package assembly may comprise the LSC 220 and the one or more edge terminals 260 on the LSC 220. Block 1020 may correspond to the stage illustrated in FIG. 6B.

In block 1030, the one or more balls 215 of the BGA may be formed on the lower surface of the substrate 210. Block 1030 may correspond to the stage illustrated in FIG. 6B.

In block 1040, solder reflow may be performed. Block 1040 may correspond to the stage illustrated in FIG. 6B.

The following should be noted regarding the flow indicated in FIG. 7-10. Unless otherwise indicated, the flow of blocks do not necessarily limit the ordering in which the blocks may be performed. In other words, the blocks may be performed in any order that is logical.

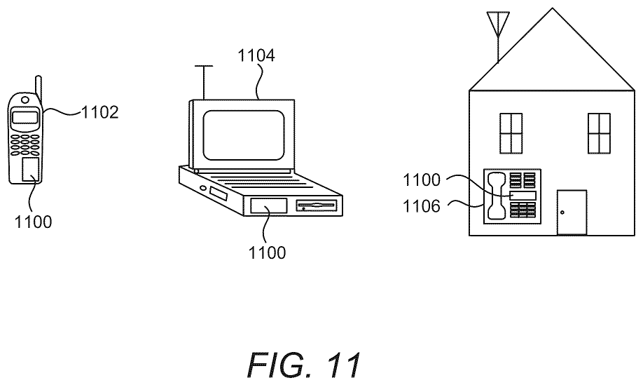

FIG. 11 illustrates various electronic devices 1100 that may be integrated with any of the aforementioned semiconductor package in accordance with various aspects of the disclosure. For example, a mobile phone device 1102, a laptop computer device 1104, and a fixed location terminal device 1106 may each be considered generally user equipment (UE) and may include one or more semiconductor packages (e.g., semiconductor package 200) as described herein. The devices 1102, 1104, 1106 illustrated in FIG. 11 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:
Clause 1: A semiconductor package, comprising: a substrate with a ball grid array (BGA) on a lower surface thereof, the BGA comprising one or more balls; a die on an upper surface of the substrate; a land-side component (LSC) on the lower surface of the substrate; and one or more edge terminals on one or more edges of the LSC, wherein at least one edge terminal comprises an edge insulator in contact with a side edge portion, an upper edge portion, and a lower edge portion, the side edge portion being a portion of a side surface of the LSC, the upper edge portion being a portion of an upper surface of the LSC near the side edge portion, and the lower edge portion being a portion of a lower surface of the LSC near the side edge portion.
Clause 2: The semiconductor package of clause 1, wherein the at least one edge terminal further comprises an edge conductor formed on side, upper and lower surfaces of the edge insulator.
Clause 3: The semiconductor package of clause 2, wherein the edge conductor is formed to provide one of power or ground to the die.
Clause 4: The semiconductor package of any of clauses 2-3, wherein the LSC comprises one or more LSC pins on the lower surface of the substrate, and wherein the edge conductor is electrically coupled with the one or more LSC pins.
Clause 5: The semiconductor package of any of clauses 2-4, wherein a keep-out-zone (KOZ) is 150 μm or less, the KOZ defining a minimum distance between the edge conductor and a nearest ball of the BGA.
Clause 6: The semiconductor package of any of clauses 2-5, further comprising: a mold on the substrate, wherein the mold encapsulates side and upper surfaces of the die; a passivation layer on the mold; and one or more through-mold vias (TMV) within the mold, wherein the one or more TMVs electrically couple one or more circuits within the passivation layer to one or more circuits within the substrate.
Clause 7: The semiconductor package of any of clauses 2-6, further comprising: a printed circuit board (PCB) below the substrate, wherein the BGA and the at least one edge terminal are electrically coupled to one or more circuits within the PCB.
Clause 8: The semiconductor package of any of clauses 1-7, wherein the die is a system-on-chip (SoC).
Clause 9: The semiconductor package of any of clauses 1-8, wherein the LSC is a passive device.
Clause 10: The semiconductor package of any of clauses 1-9, wherein the die comprises one or more die pins on the upper surface of the substrate, wherein the LSC comprises one or more LSC pins on the lower surface of the substrate, and wherein the die and the LSC are electrically coupled to each other through the one or more die pins, the one or more LSC pins, and one or more conductive circuits within the substrate.
Clause 11: The semiconductor package of any of clauses 1-10, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
Clause 12: A method of fabricating a semiconductor package, the method comprising: forming a substrate with a ball grid array (BGA) on a lower surface thereof, the BGA comprising one or more balls; providing a die on an upper surface of the substrate; providing a land-side component (LSC) on the lower surface of the substrate; and forming one or more edge terminals on one or more edges of the LSC, wherein at least one edge terminal comprises an edge insulator in contact with a side edge portion, an upper edge portion, and a lower edge portion, the side edge portion being a portion of a side surface of the LSC, the upper edge portion being a portion of an upper surface of the LSC near the side edge portion, and the lower edge portion being a portion of a lower surface of the LSC near the side edge portion.
Clause 13: The method of clause 12, wherein the at least one edge terminal further comprises an edge conductor formed on side, upper and lower surfaces of the edge insulator.
Clause 14: The method of clause 13, wherein the edge conductor is formed to provide one of power or ground to the die.
Clause 15: The method of any of clauses 13-14, wherein the LSC comprises one or more LSC pins on the lower surface of the substrate, and wherein the edge conductor is electrically coupled with the one or more LSC pins.
Clause 16: The method of any of clauses 13-15, wherein a keep-out-zone (KOZ) is 150 μm or less, the KOZ defining a minimum distance between the edge conductor and a nearest ball of the BGA.
Clause 17: The method of any of clauses 13-16, further comprising: forming a mold on the substrate, wherein the mold encapsulates side and upper surfaces of the die; forming a passivation layer on the mold; and forming one or more through-mold vias (TMV) within the mold, wherein the one or more TMVs electrically couple one or more circuits within the passivation layer to one or more circuits within the substrate.
Clause 18: The method of any of clauses 13-17, further comprising: providing a printed circuit board (PCB) below the substrate, wherein the BGA and the at least one edge terminal are electrically coupled to one or more circuits within the PCB.
Clause 19: The method of any of clauses 12-18, wherein the die is a system-on-chip (SoC).
Clause 20: the Method of Any of Clauses 12-19, Wherein the Lsc Is a Passive device.
Clause 21: The method of any of clauses 12-20, wherein the die comprises one or more die pins on the upper surface of the substrate, wherein the LSC comprises one or more LSC pins on the lower surface of the substrate, and wherein the die and the LSC are electrically coupled to each other through the one or more die pins, the one or more LSC pins, and one or more conductive circuits within the substrate.
Clause 22: The method of any of clauses 12-21, wherein forming the one or more edge terminals comprises: forming bumps on LSC pins of the LSC, wherein the LSC is one of a plurality of LSCs of a wafer; singulating the LSC from the wafer; dipping one or more edges of the LSC in termination ink to form one or more edge insulators; and plating conductive material on the one or more edge insulators to form corresponding one or more edge conductors.
Clause 23: The method of any of clauses 12-22, wherein providing the LSC comprises: providing a first package assembly comprising at least the die on the upper surface of the substrate; placing a second package assembly on the lower surface of the substrate, the second package assembly comprising the LSC and the one or more edge terminals on the LSC; forming the one or more balls of the BGA on the lower surface of the substrate; and performing solder reflow.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor package, comprising:
a substrate with a ball grid array (BGA) on a lower surface thereof, the BGA comprising one or more balls;
a die on an upper surface of the substrate;
a land-side component (LSC) on the lower surface of the substrate; and
one or more edge terminals on one or more edges of the LSC, wherein at least one edge terminal comprises an edge insulator in contact with a side edge portion, an upper edge portion, and a lower edge portion, the side edge portion being a portion of a side surface of the LSC, the upper edge portion being a portion of an upper surface of the LSC near the side edge portion, and the lower edge portion being a portion of a lower surface of the LSC near the side edge portion.

2. The semiconductor package of claim 1, wherein the at least one edge terminal further comprises an edge conductor formed on side, upper and lower surfaces of the edge insulator.

3. The semiconductor package of claim 2, wherein the edge conductor is formed to provide one of power or ground to the die.

4. The semiconductor package of claim 2,
wherein the LSC comprises one or more LSC pins on the lower surface of the substrate, and
wherein the edge conductor is electrically coupled with the one or more LSC pins.

5. The semiconductor package of claim 2, wherein a keep-out-zone (KOZ) is 150 μm or less, the KOZ defining a minimum distance between the edge conductor and a nearest ball of the BGA.

6. The semiconductor package of claim 2, further comprising:
a mold on the substrate, wherein the mold encapsulates side and upper surfaces of the die;
a passivation layer on the mold; and
one or more through-mold vias (TMV) within the mold, wherein the one or more TMVs electrically couple one or more circuits within the passivation layer to one or more circuits within the substrate.

7. The semiconductor package of claim 2, further comprising:
a printed circuit board (PCB) below the substrate,
wherein the BGA and the at least one edge terminal are electrically coupled to one or more circuits within the PCB.

8. The semiconductor package of claim 1, wherein the die is a system-on-chip (SoC).

9. The semiconductor package of claim 1, wherein the LSC is a passive device.

10. The semiconductor package of claim 1,
wherein the die comprises one or more die pins on the upper surface of the substrate,
wherein the LSC comprises one or more LSC pins on the lower surface of the substrate, and
wherein the die and the LSC are electrically coupled to each other through the one or more die pins, the one or more LSC pins, and one or more conductive circuits within the substrate.

11. The semiconductor package of claim 1, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

12. A method of fabricating a semiconductor package, the method comprising:
forming a substrate with a ball grid array (BGA) on a lower surface thereof, the BGA comprising one or more balls;
providing a die on an upper surface of the substrate;
providing a land-side component (LSC) on the lower surface of the substrate; and
forming one or more edge terminals on one or more edges of the LSC, wherein at least one edge terminal comprises an edge insulator in contact with a side edge portion, an upper edge portion, and a lower edge portion, the side edge portion being a portion of a side surface of the LSC, the upper edge portion being a portion of an upper surface of the LSC near the side edge portion, and the lower edge portion being a portion of a lower surface of the LSC near the side edge portion.

13. The method of claim 12, wherein the at least one edge terminal further comprises an edge conductor formed on side, upper and lower surfaces of the edge insulator.

14. The method of claim 13, wherein the edge conductor is formed to provide one of power or ground to the die.

15. The method of claim 13,
wherein the LSC comprises one or more LSC pins on the lower surface of the substrate, and
wherein the edge conductor is electrically coupled with the one or more LSC pins.

16. The method of claim 13, wherein a keep-out-zone (KOZ) is 150 μm or less, the KOZ defining a minimum distance between the edge conductor and a nearest ball of the BGA.

17. The method of claim 13, further comprising:
forming a mold on the substrate, wherein the mold encapsulates side and upper surfaces of the die;
forming a passivation layer on the mold;
forming one or more through-mold vias (TMV) within the mold, wherein the one or more TMVs electrically couple one or more circuits within the passivation layer to one or more circuits within the substrate; and
providing a printed circuit board (PCB) below the substrate,
wherein the BGA and the at least one edge terminal are electrically coupled to one or more circuits within the PCB.

18. The method of claim 12,
wherein the die comprises one or more die pins on the upper surface of the substrate,
wherein the LSC comprises one or more LSC pins on the lower surface of the substrate, and
wherein the die and the LSC are electrically coupled to each other through the one or more die pins, the one or more LSC pins, and one or more conductive circuits within the substrate.

19. The method of claim 12, wherein forming the one or more edge terminals comprises:
forming bumps on LSC pins of the LSC, wherein the LSC is one of a plurality of LSCs of a wafer;
singulating the LSC from the wafer;
dipping one or more edges of the LSC in termination ink to form one or more edge insulators; and
plating conductive material on the one or more edge insulators to form corresponding one or more edge conductors.

20. The method of claim 12, wherein providing the LSC comprises:
providing a first package assembly comprising at least the die on the upper surface of the substrate;
placing a second package assembly on the lower surface of the substrate, the second package assembly comprising the LSC and the one or more edge terminals on the LSC;
forming the one or more balls of the BGA on the lower surface of the substrate; and
performing solder reflow.
